(19) United States
(12) Patent Application Publication
(10) Pub. No.: US 2005/0285627 A1
(43) Pub. Date: Dec. 29, 2005

(54) Input enable/disable circuit

(76) Inventor: Eugene B. Hinterscher, McKinney, TX (US)

Correspondence Address: TEXAS INSTRUMENTS INCORPORATED, P O BOX 655474, M/S 3999, DALLAS, TX, 75265, US

(21) Appl. No.: 10/875,038

(22) Filed: Jun. 22, 2004

(51) Int. Cl. H03K 19/096

(52) U.S. Cl. 326/96

(57) ABSTRACT

An integrated circuit control circuit disables the input circuit and the output circuit of the integrated circuit. On enabling the integrated circuit, the input circuit is enabled before the output circuit is enabled to prevent a race condition which generates a glitch in the output signal.

### BAC TECHNICAL FIELD OF THE INVENTION

The present invention relates to an input enable/disable circuit and more specifically to an input enable/disable circuit for an integrated circuit.

### BACKGROUND OF THE INVENTION

The power consumed by an integrated circuit device has always been important in the design of that device. The power consumed by the device is reflected in the design of the package to carry away the heat that is produced. In addition, heat sinks and cooling fans may be needed to carry away the excess heat. More recently, the reduction in the power consumed by a device has been driven by battery powered portable electronic devices and the need to conserve energy under such programs such as the “Energy Star” program. Portable electronic devices such as cellular telephones, PDAs, laptop computers, digital cameras, and portable electronic games are just some examples of portable electronic devices that are battery powered. Many of these devices have been power hungry and thus are manufactured with or often used with rechargeable batteries. Rechargeable batteries minimize the cost of the power drain, but the size, weight and cost of the battery directly affects the usability, portability and cost of these devices. Furthermore, the continued miniaturization of these devices again brings, heat dissipation into the forefront. Even in areas where power is readily available, such as a home, office or automobile, there has been a movement to reduce the power consumed by electronic devices in order to reduce the electrical energy requirements and thus relieve stresses on power grids and the environment. Therefore, many devices meant for these environments also incorporate measures to reduce the power of the device. These devices are subject to miniaturization as well, although not to the same degree as portable devices. Therefore, heat dissipation remains a concern.

One way to reduce the power consumed by an electronic device and the heat generated thereby is to stop operations within those electronic circuits that are not needed at any one particular time and to resume operation when they are needed. The power dissipated by an integrated circuit is composed of its static power requirements and its dynamic power requirements. In a properly designed MOS integrated circuit, for example, the static requirement for power is only the leakage current of the transistor devices, which approaches zero. The dynamic power requirements are based upon the switching transitions of the device, and are primarily concerned with the charging and discharging of capacitances within the integrated circuit. Many of these capacitances within MOS integrated circuit are parasitic capacitances. The power dissipation of the integrated circuit can be defined as:
P=CPD_{DIS}×V_{CC}²×frequency+I_{CC}V_{CC}
The term CPDdis is the power dissipation capacitance which is defined as a measure of the current through the device when one bit is switching at a standard frequency. The term I_{CC}V_{CC} is a measure of the static power consumed by the device, which approaches zero in a properly designed MOS device.

One way to reduce the current in a device is to disable the outputs. However, if the input remains enabled, there could be switching transitions that will occur within the device which will continue to consume power. If both the inputs and outputs are disabled, then race situation can occur. This is shown in FIG. 1. FIG. 1 shows an integrated circuit generally as 100. An input signal is coupled to terminal 102 which is applied to the input circuit 106. The output of the input circuit 106 is coupled to a functional circuit, here illustrated as a logic block 108, which generates an output at 110, which in turn is applied to the output circuit 114. The output circuit 114 provides an output on output terminal 116. Both the input circuit 106 and output circuit 114 are coupled to an output enable signal NOE applied to terminal 118 and coupled to the OE terminal 104 of input circuit 106 via line 120 and via line 122 to the OE terminal 112 of the output circuit 114. The signal NOE is used to control both the input and the output circuits 106, 114 respectively. At the time the input and output circuits 106, 114 are disabled a logic high is waiting on the input terminal 102. At the same time, the output of the logic block 108, signal S1, is at a logic low which is the input of the output circuit 114. The signal waiting at the input terminal 102 does not propagate through the logic circuit, because the input has been disabled. The signal S1 does not produce an output signal at terminal 116, because the output has been disabled. In this circuit, the input and output are enabled at the same time via the signal NOE. The output signal at pin 116 is shown in FIG. 4A as signal 402. The enable occurs at 404 which causes the output glitch shown in FIG. 4A because the circuit first produces the output signal caused by the signal S1 and then produces an output signal caused by the input signal on pin 102 which has now propagated through the logic block circuit 108 and appears on input pin 110 of output circuit 114.

Accordingly, there is a need for integrated circuit in which the input and output can be disabled and in which there is no glitch created in the output when the circuit is enabled.

### SUMMARY OF THE INVENTION

This and other objects and features are attained, in accordance with one aspect of the invention by an integrated circuit comprising an input circuit and an output circuit. A functional circuit is coupled between the input circuit and the output circuit. A disable circuit is coupled to the input circuit for disabling an input to the input circuit, whereby the power consumed by the integrated circuit is reduced during inactive periods.

A second aspect of the invention includes a method of preventing or reducing glitches on an output of an integrated circuit having a functional circuit thereon coupled to an input of the integrated circuit and the output, wherein the input is first disabled and later enabled. A head start signal is supplied to the input of the integrated circuit for enabling the input prior to enabling the output. An output enable signal is supplied to the output of the integrated circuit a predetermined time after the input was enabled, wherein the predetermined time allows a signal applied at the input to generate a signal at the output.

### BRIEF DESCRIPTION OF THE DRAWINGS

FIG. 1 is a block diagram of a circuit in which the input and output are enabled simultaneously;

FIG. 2A is a block diagram of an input and output disable/enable circuit according the present invention;

FIG. 2B is a circuit diagram of element 224 in FIG. 2A;

FIGS. 3A and 3B illustrate the transition of the control voltage used to control the circuit 224;

FIG. 4A shows the output signal for the circuit shown in FIG. 1; and

FIG. 4B shows the output signal for the circuit shown in FIG. 2A.

### DETAILED DESCRIPTION OF THE PRESENT INVENTION

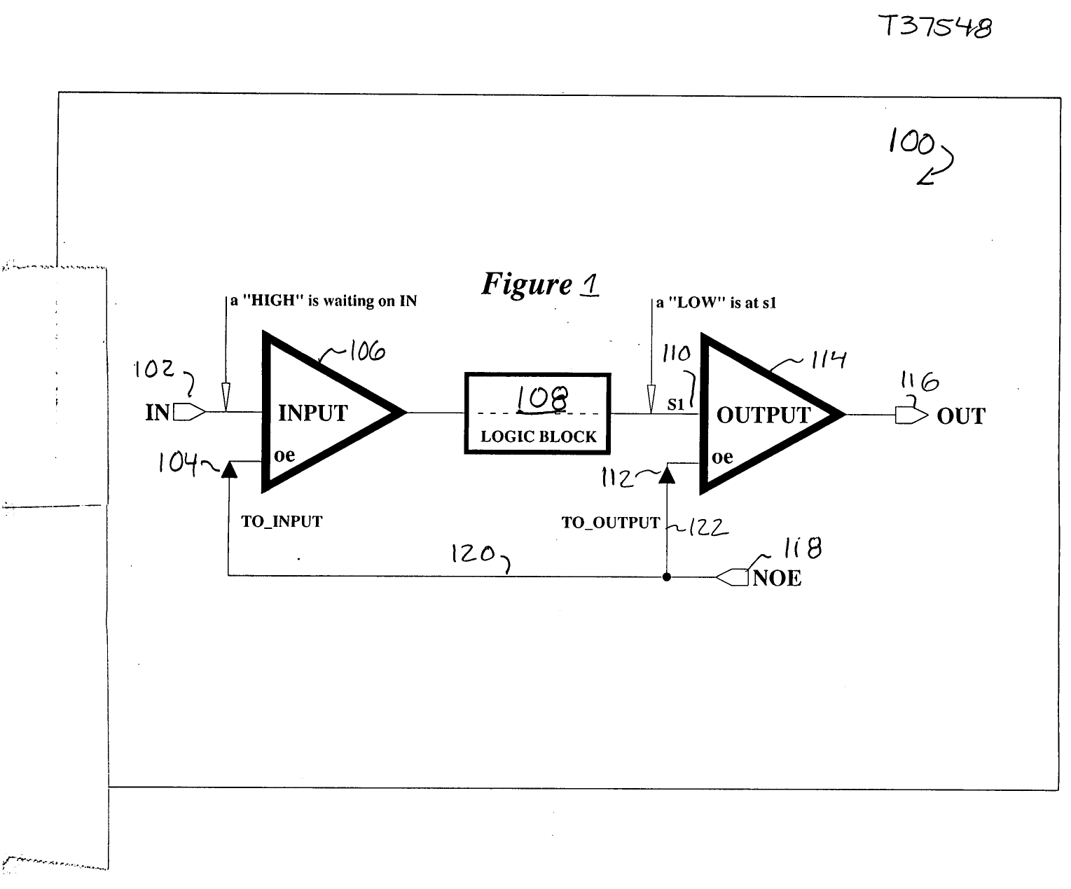

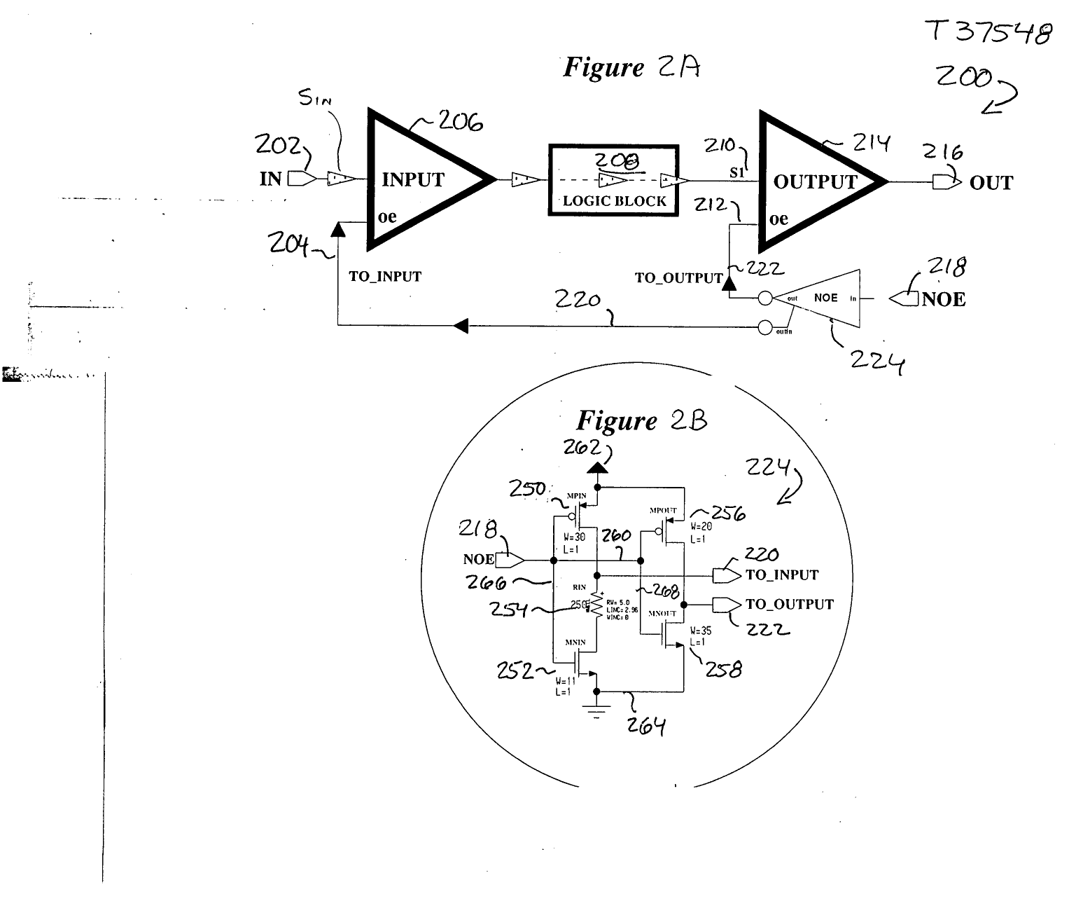

FIG. 2A shows a block diagram of a circuit in accordance with the present invention generally as 200. The elements of the circuit of FIG. 2A that are common with circuit of FIG. 1 have similar reference numerals. Input circuit 206 has an input from terminal 202 and an output enable input at 204. The output of input circuit 206 is coupled to a logic block 208 which has an output signal S1 that is applied to input 210 of output circuit 214. Output circuit 214 has an output enable signal that is received on line 212. Terminal 216 is the output terminal for the output circuit 214. The output enable control signal NOE is coupled to terminal 218 and input to circuit 224. Circuit 224 generates and input circuit output enable signal on line 220 and output circuit output enable signal on line 222.

The signal S_{IN} is the signal that appears at the input 202 to the input circuit 206 which is show diagrammatically as an arrow in FIG. 2A. The circuit 224 will generate an output enable signal to the input circuit 206 that gives the input circuit 206 a “head start” over the output circuit 214. That is, the input circuit will be enabled first before the output circuit will be enabled. This time delay between enabling the input circuit 206 and the output circuit 214 is sufficient to allow the signal S_{IN} to propagate through the input circuit 206, and logic block 208 to the input 210 of the output circuit 214. Then the output circuit 214 will receive a separate output enable signal on line 222 which will allow the signal on input 210 to propagate the output 216.

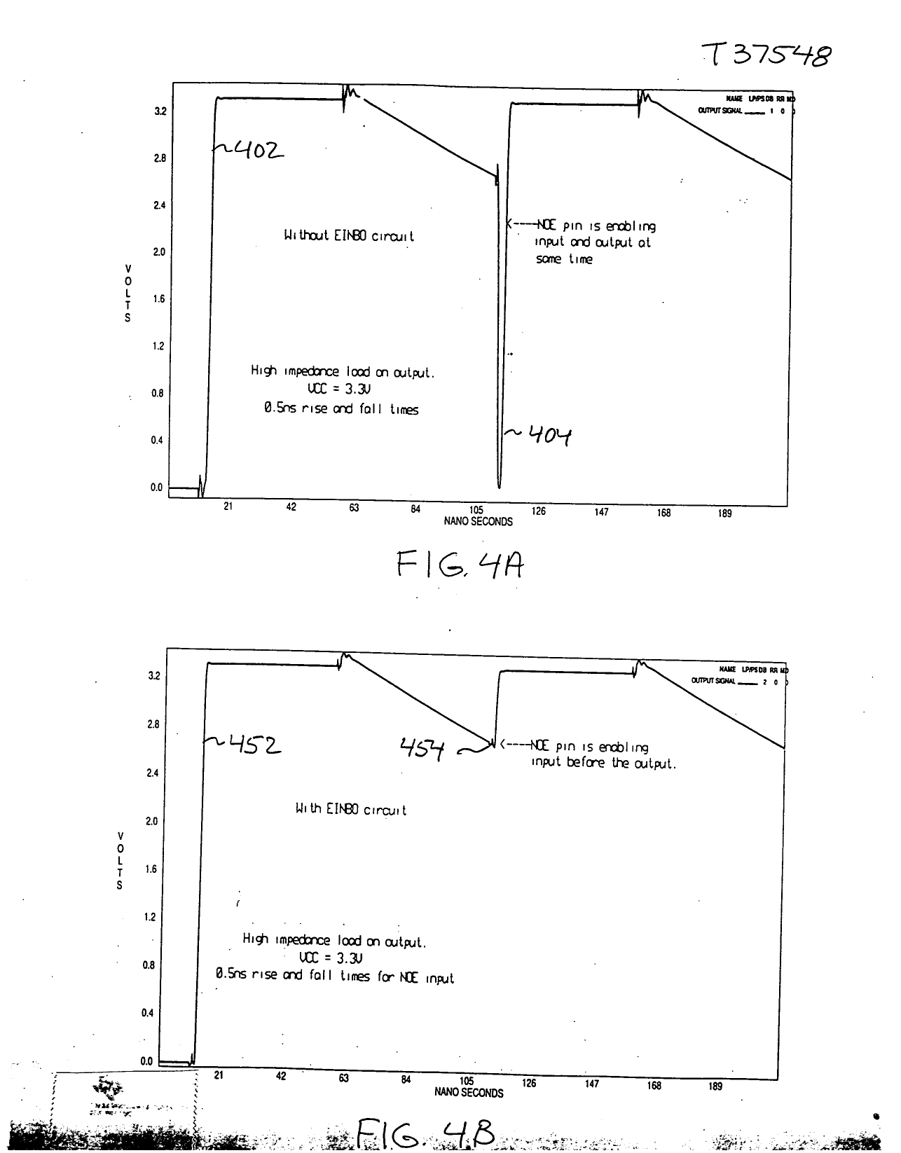

Referring to FIG. 4B, the signal 452 is the signal on output terminal 216. At the time that the output circuit is enabled, at 454 in FIG. 4B, it can be seen that the glitch shown as 404 in FIG. 4A is missing because there is no race situation at the output. That is, the proper input signal has been allowed to propagate through the circuit and appear as an input to the output circuit before the output is enabled. Thus the glitch 404 is eliminated.

FIG. 2B shows the details of the circuit 224 of FIG. 2A. The input signal NOE supplied to terminal 218 which is connected via line 266 to the gate of a PMOS transistor 250. The source of transistor 250 is coupled to a voltage supply 262 and the drain of transistor 250 is coupled via a resistor 254 to the drain of an NMOS transistor 252. The gate of the NMOS transistor is coupled via line 266 to the signal NOE at terminal 218 and the source of the NMOS transistor 252 is coupled to ground. A second PMOS transistor 256 has its source coupled to the voltage source 262 and its drain coupled to the drain of a second NMOS transistor 258. The source of transistor 258 is coupled via line 264 to ground. The gates of transistors 256 and 258 are connected together by line 268 and coupled via line 260 to the signal NOE at terminal 218. The output on line 220, which is the output enable signal for the input circuit 206, is taken at the drain of transistor 250. The output enable signal on line 222 for the output circuit is taken at the drain of transistor 258.

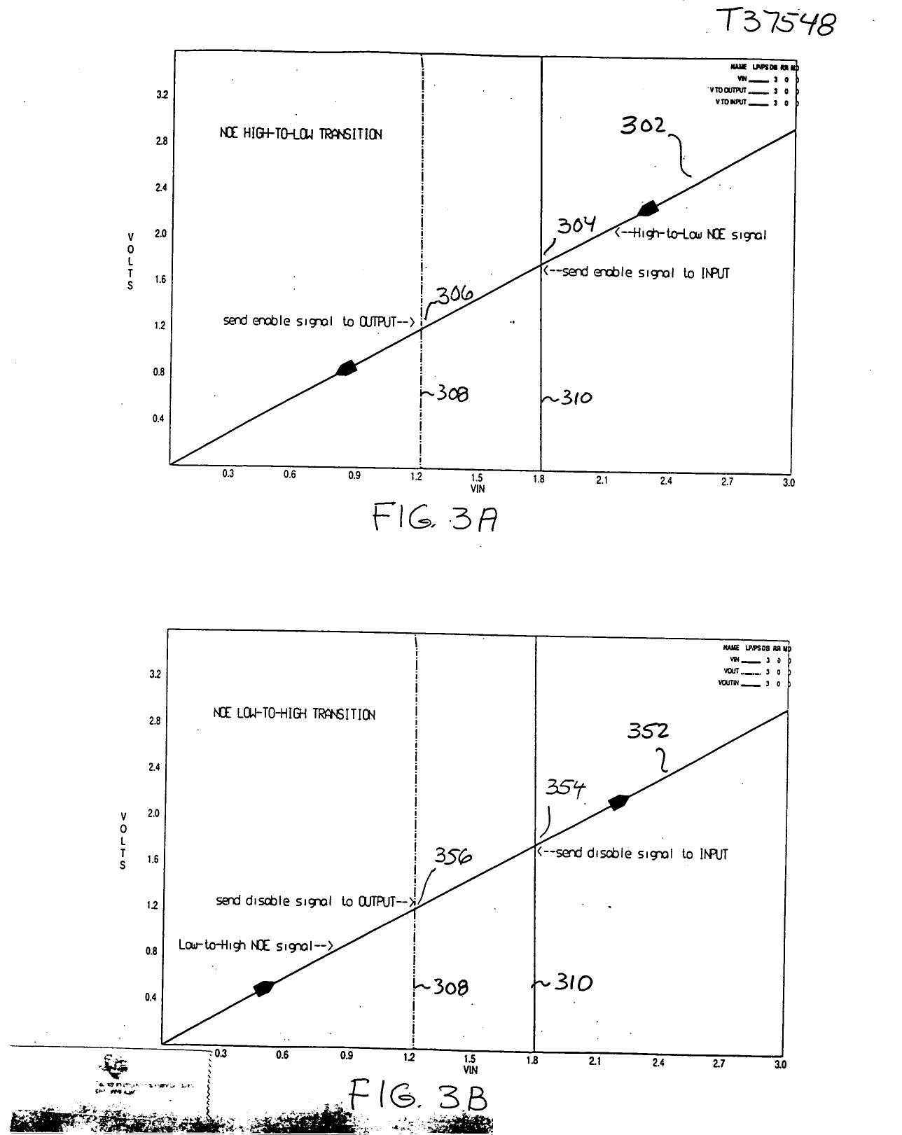

The operation of the circuit 224 will now be explained in conjunction with FIGS. 3A and 3B. In FIG. 3A, the signal NOE is shown as 302 which illustrates the high to low transition of the signal. In FIG. 3A, the signal is shown only as a change in DC level to illustrate the principles of the present invention. However, the actual shape of the signal and the slope thereof are left to the designer of the circuit to implement according to the needs of the circuit. The slope of the change in DC level, for example, determines the amount of time of the enablement of the inputs circuit 206 and the output circuit 214. As shown in FIG. 3A, when the signal 302 drops to the first threshold level 310, at 304, an enable signal is sent to the input circuit 206 at input terminal 204 to enable the input. Thus the signal S_{IN} will go out through the input circuit, through the logic block 208, and to the input 210 to the output circuit 214. The progress of the signal from the input 202 to the input 210 is shown diagrammatically by the arrows along the path in FIG. 2A. When the signal 302 drops to the voltage threshold 308, at 306, the output enable signal on line 222 to input 212 of the output circuit 214 is generated to enable the signal present on input 210, signal S1, to propagate to the output 216. Thus, the output glitch is eliminated.

FIG. 3B shows the low to high transition of the NOE signal as 352. When the signal 352 reaches the first threshold 308, at 356, it sends a disable signal to the output circuit 214 via line 222. When the signal 352 rises to the second threshold 310, at 354, the circuit 224 sends a disable signal to the input circuit 206 via line 220. Thus, no transitions will take place within the circuit.

It is not necessary to practice the present invention that both the input circuit 206 and output circuit 214 be disabled at different times. However, utilizing the circuit 224, will necessarily generate the two signals as the two thresholds are crossed. Those skilled in the art would recognize it is possible to modify the circuit 224 so that both output disable signals are generated at the same time by altering the circuit to respond differently to the rising signal than it does to the falling signal either by detecting the rise in the control signal NOE or by detecting the state of the input circuit 206 or output circuit 214 and providing a different response when they are enabled than when they are disabled. This would add to the circuitry of the circuit 224 but not depart from the teaching of the present invention.

The present invention solves the problem of generating the output glitch in both the input of a circuit and the output of a circuit are disabled and later enabled. The present invention avoids a need for triggering a single NOE input threshold and the using delay inverters to enable the output in order to avoid the race condition. The advantage of the present invention is operation over a large range of supply voltages whereas the use of delayed inverters can have slower enable/disable times than required. The present invention works over a larger range of voltages, such as 1.1 to 3.6 volts, for example, as is especially useful at lower voltages, that is at the 1.1 volt level.

While the invention has been shown and described with reference to preferred embodiments thereof, it is well understood by those skilled in the art that various changes and modifications can be made in the invention without departing from the spirit and scope of the invention as defined by the appended claims.

1. An integrated circuit comprising:
an input circuit;
an output circuit;
a functional circuit coupled between the input circuit and the output circuit;
a disable circuit coupled to the input circuit for disabling an input to the input circuit, whereby the power consumed by the integrated circuit is reduced during inactive periods.

2. The integrated circuit of claim 1 further comprising coupling the disable circuit to the output circuit for disabling an output of the output circuit.

3. The integrated circuit of claim 2 wherein the disable circuit disables the output circuit first and then disables the input circuit.

4. The integrated circuit of claim 2 wherein the disable circuit disables the output circuit at a first trigger voltage level of a control signal and disables the input circuit at a second trigger voltage level of the control signal, wherein the first and second trigger voltage levels are at different voltage levels.

5. The integrated circuit of claim 3 wherein the disable circuit disables the output circuit at a first trigger voltage level of a control signal and disables the input circuit at a second trigger voltage level of the control signal, wherein the first and second trigger voltage levels are at different voltage levels.

6. The integrated circuit of claim 2 wherein the disable circuit enables the input circuit first and then the output circuit.

7. The integrated circuit of claim 2 wherein the disable circuit enables the input circuit at a third trigger voltage level of a control signal and enables the output circuit at a fourth trigger voltage level of the control signal, wherein the third and fourth trigger voltage levels are at different voltage levels.

8. The integrated circuit of claim 6 wherein the disable circuit enables the input circuit at a third trigger voltage level of a control signal and enables the output circuit at a fourth trigger voltage level of the control signal, wherein the third and fourth trigger voltage levels are at different voltage levels.

9. The integrated circuit of claim 3 wherein the disable circuit enables the input circuit first and then the output circuit.

10. The integrated circuit of claim 4 wherein the disable circuit enables the input circuit at a third trigger voltage level of a control signal and enables the output circuit at a fourth trigger voltage level of the control signal, wherein the third and fourth trigger voltage levels are at different voltage levels.

11. The integrated circuit of claim 5 wherein the disable circuit enables the input circuit at a third trigger voltage level of a control signal and enables the output circuit at a fourth trigger voltage level of the control signal, wherein the third and fourth trigger voltage levels are at different voltage levels.

12. The integrated circuit of claim 1 wherein the functional circuit is a logic circuit.

13. The integrated circuit of claim 2 wherein the functional circuit is a logic circuit.

14. The integrated circuit of claim 11 wherein the functional circuit is a logic circuit.

15. A method of preventing or reducing glitches on an output of an integrated circuit having a functional circuit thereon coupled to an input of the integrated circuit and the output, wherein the input is first disabled and later enabled, comprising:
supplying a head start signal to the input of the integrated circuit for enabling the input prior to enabling the output;
supplying an output enable signal to the output of the integrated circuit a predetermined time after the input was enabled, wherein the predetermined time allows a signal applied at the input to generate a signal at the output.

16. The method of claim 15 wherein a control circuit generates the head start signal when a control signal is at a first trigger voltage level and generates the output enable signal when the control signal is at a second trigger voltage level, the first and second trigger voltage levels being at different voltages.

17. The method of claim 15 further comprising generating a first disable signal to the output of the integrated circuit and a second disable signal to the input of the integrated circuit.

18. The method of claim 17 further comprising generating the first disable signal when a control signal is at a third trigger voltage level and generating the second disable signal when the control signal is at a fourth trigger voltage level, the third and fourth trigger voltage levels being at different voltages.

19. The method of claim 16 further comprising generating a first disable signal to the output of the integrated circuit and a second disable signal to the input of the integrated circuit, generating the first disable signal when a control signal is at a third trigger voltage level and generating the second disable signal when the control signal is at a fourth trigger voltage level, the third and fourth trigger voltage levels being at different voltages.

20. The method of claim 19 wherein a signal control circuit generates the head start signal, the output enable signal and the first and second disable signals when the control signal is at first, second, third and fourth trigger voltage levels, respectively.
